(19) United States
(12) Patent Application Publication
(10) Pub. No.: US 2019/0208579 A1
(43) Pub. Date: Jul. 4, 2019

(54) INFRARED SURFACE EMITTER

(71) Applicant: Heraeus Noblelight GmbH, Hanau (DE)

(72) Inventors: Lotta GAAB, Darmstadt (DE); Thomas PIELA, Hanau (DE); Christoph STERNKIKER, Hanau (DE); Jürgen WEBER, Kleinostheim (DE)

(21) Appl. No.: 16/334,195

(22) PCT Filed: Aug. 22, 2017
(86) PCT No.: PCT/EP2017/071086

§ 371 Date: Mar. 18, 2019

(30) Foreign Application Priority Data
Sep. 26, 2016 (DE) 10 2016 118 137.4

(51) Int. Cl. H05B 3/26; H05B 3/24; H01L 21/67; H01L 21/673

(52) U.S. Cl. CPC H05B 3/265; H05B 3/262; H05B 3/24; H01L 21/67098; H05B 2203/032; H05B 2203/003; H05B 2203/007; H05B 2203/013; H01L 21/673

(57) ABSTRACT

Infrared panel radiators are provided including a carrier with a heating surface, and a printed conductor made of an electrically conductive resistor material that generates heat when current flows through it. The printed conductor is applied to a printed conductor occupation surface of the carrier. The printed conductor includes a first printed conductor section for generation of a first power per unit area and a second printed conductor section for generation of a second power per unit area that differs from the first power per unit area. The carrier contains a composite material including an amorphous matrix component and an additional component in the form of a semiconductor material. The first printed conductor section and the second printed conductor section are circuited in series and differ from each other by their occupation density and/or by their conductor cross-section.

### CROSS REFERENCE TO RELATED APPLICATIONS

This application is a U.S. National Phase filing of international patent application number PCT/EP2017/071086 filed Aug. 22, 2017 that claims the priority of German patent application number 102016118137.4 filed Sep. 26, 2016. The disclosures of these applications are hereby incorporated by reference in their entirety.

### FIELD

The invention relates to infrared panel radiators, and more particularly, to infrared panel radiators including a carrier with a heating surface, and a printed conductor made of an electrically conductive resistor material applied to a printed conductor occupation surface of the carrier.

### BACKGROUND

It is common to use infrared panel radiators for thermal treatment of heating goods. Known infrared panel radiators can differ in design. For example, infrared panel radiators are known, in which multiple infrared emitters with a cylinder-shaped emitter tube are arranged appropriately in an emitter module such that the longitudinal axes of the emitter tubes extend parallel to each other in a plane. Moreover, infrared panel radiators of the type mentioned above are known, in which a resistor heating element is applied directly to the surface of a panel-like carrier.

The two designs described above differ by their mode of heat transmission. Whereas, in the former case, the heat transmission from a heating element arranged in the emitter tube to the emitter tube takes place mainly by heat radiation, the heating element in the latter case is in direct contact with the panel-like carrier such that the heat transmission from the heating element to the carrier takes place mainly by heat conduction and convection.

Infrared panel radiators having a heating element applied to the carrier show good power efficiency. If a voltage is applied to the resistor heating element of these infrared panel radiators, the infrared panel radiator is operated by an essentially constant electrical power over its entire length.

However, it has been evident that operation of the heating element with a constant electrical power can be associated with temperature differences, in particular with an inhomogeneous temperature distribution on the heating surface of the carrier. Especially at the periphery of the carrier, it is common to measure lower temperatures then, for example, in the middle region of the carrier. One underlying reason is that higher energy losses due to convection can occur at the periphery of the carrier as compared to the middle region. This is associated with a lower temperature in particular at the periphery of the carrier and, with respect to the entire carrier, with an inhomogeneous temperature distribution.

It is therefore known that the periphery and the middle region of a carrier need to be heated at two different degrees in order to attain a carrier temperature that is as homogeneous as possible and, along with it, a radiation emission of the actual heating surface that is as homogeneous as possible.

Infrared panel radiators with a panel-like carrier are known, in which the printed conductor includes multiple printed conductor sections that are circuited in parallel. Circuiting them in parallel is to contribute to the printed conductor having the lowest possible overall resistance such that it can be operated at high operating currents and, along with it, at high power. For compensation of peripheral effects, the printed conductor sections are operated at different power per unit area, whereby the printed conductor sections usually are generated through the use of printing techniques, for example, by screen or inkjet printing. Usually, these radiators have a printed conductor section that can be operated at a higher power per unit area associated to the periphery of the carrier. This is advantageous in that convection-related temperature losses in the peripheral zones can be compensated for by the higher power per unit area of the printed conductor section assigned to this region.

From DE 10 2014 108 356 A1 an infrared panel radiator is known in which a resistor structure is applied to a carrier. The resistor structure includes an inner printed conductor and, circuited in parallel to it, and outer printed conductor, which differ in their resistance. A resistor structure of this type makes use of the effect that the printed conductor with the lower resistance makes a larger contribution to the heating power. This is a means of counteracting the formation of so-called “cold spots” and/or a power drop at the periphery.

Circuiting heating resistors in parallel is advantageous in that these have a particularly low overall resistance. At a given constant operating voltage, a low overall resistance is associated with a high operating current and allows the infrared panel radiator to be operated at high power. However, providing heating resistors circuited in parallel has an impact on the printed conductor design, i.e., the arrangement and geometry of the printed conductor sections. In particular, the desired temperature distribution might define the resistance of the parallel partial circuits and the position of the parallel junctions from the main circuit. As a result, due to the given position of the junctions of the parallel circuit, it may not be feasible any longer to freely select the printed conductor design. Moreover, a higher printed conductor occupation density may result at the parallel junction, which in turn has an influence on the temperature distribution on the carrier, in particular of the heating surfaces.

### SUMMARY

It is therefore an object of the invention to devise an infrared panel radiator with high irradiation power that is designed for the emission of radiation at an irradiation power that is as homogeneous as possible.

According to an exemplary embodiment of the invention, an infrared panel radiator is provided. The infrared panel radiator includes a carrier with a heating surface, and a printed conductor made of an electrically conductive resistor material that generates heat when current flows through it. The printed conductor is applied to a printed conductor occupation surface of the carrier. The printed conductor includes a first printed conductor section for generation of a first power per unit area and a second printed conductor section for generation of a second power per unit area that differs from the first power per unit area. The carrier contains a composite material including an amorphous matrix component and an additional component in the form of a semiconductor material. The first printed conductor section and the second printed conductor section are circuited in series and differ from each other by their occupation density and/or by their conductor cross-section.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIG. 1 illustrates an infrared panel radiator with a printed conductor that has a higher occupation density in the peripheral region, than in the middle region, in accordance with an exemplary embodiment of the invention;

FIG. 2 illustrates an infrared panel radiator with a printed conductor that has a lower conductor cross-section in the peripheral region, than in the middle region, in accordance with an exemplary embodiment of the invention;

FIG. 3 illustrates an infrared panel radiator, as well as a thermal image showing the temperature distribution of the substrate on the side of this infrared panel radiator that is occupied by the printed conductor, in accordance with an exemplary embodiment of the invention;

FIG. 4 illustrates an infrared panel radiator in which printed conductor sections with alternating high and low electrical resistance are circuited in series in accordance with an exemplary embodiment of the invention;

FIG. 5 illustrates an infrared panel radiator with a carrier made of a single material in accordance with an exemplary embodiment of the invention;

FIG. 6 illustrates an infrared panel radiator with a carrier with three layers of material in accordance with an exemplary embodiment of the invention; and

FIG. 7 illustrates an infrared panel radiator in which the carrier includes a jacketed carrier core in accordance with an exemplary embodiment of the invention.

### DETAILED DESCRIPTION

Exemplary embodiments of the invention relate to an infrared panel radiator including a carrier with a heating surface and with a printed conductor that is made of an electrically conductive resistor material that generates heat when current flows through it and is applied to a printed conductor occupation surface of the carrier, whereby the printed conductor includes a first printed conductor section for generation of a first power per unit area and a second printed conductor section for generation of a second power per unit area that differs from the first power per unit area.

Exemplary embodiments of the invention relate to infrared panel radiators that show a heating surface with panel-like two- or three-dimensional emission characteristics; their panel-like emission characteristics makes them easy to adapt to the geometry of a surface of heating goods to be heated such that homogeneous irradiation of two- or surfaces of three-dimensional heating goods is made feasible.

Infrared panel radiators according to exemplary embodiments of the invention are used for thermal heating processes, for example, for thermal treatment of semiconductor wafers in the semiconductor or photovoltaics industries, in the printing industry, or in plastics processing. Infrared panel radiators according to the invention may be used, for example, for polymerisation of plastic materials, for curing of lacquers, or for drying of paints. Moreover, they can be used in a multitude of drying processes, for example, in the production of films or yarns, for fabrication of models, samples, prototypes, tools or finished products (Additive Manufacturing). Another important application field is the production of flexible printed electronics, in particular, in the reel-to-reel procedure (R2R procedure), in which drying and sintering processes proceed directly sequentially.

The object specified above is solved according to exemplary embodiments of the invention based on an infrared panel radiator of the aforementioned type, in that the carrier contains a composite material that includes an amorphous matrix component and an additional component in the form of a semiconductor material, and in that the first printed conductor section and the second printed conductor section are circuited in series and differ from each other by their occupation density and/or by their conductor cross-section.

Aspects of the invention are based on the finding that an infrared panel radiator with a high radiation intensity and particularly homogeneous radiation emission can be attained if, on the one hand, the infrared panel radiator is made from a composite material with a high emissivity and if, on the other hand, the printed conductor design can be adapted to the composite material by multiple printed conductor sections being circuited in series, in that the printed conductor sections differ from each other by their occupation density and/or by their conductor cross-section. What this adaptability attains is that the heating surface emits IR radiation at a homogeneous irradiation intensity or, in other words, that an essentially homogeneous temperature distribution on the heating surface is attained upon application of a voltage to the printed conductor.

Accordingly, the infrared panel radiator according to exemplary embodiments of the invention differs from conventional infrared panel radiators by two aspects, namely, on the one hand, the chemical composition of the carrier or at least of a part of the carrier that is made from a specific composite material, and, on the other hand, by the printed conductor design that is specifically adapted to the composition of the composite material.

Due to the carrier having an amorphous matrix component and an additional component in the form of a semiconductor material, a carrier that can take on an energy-rich excited state upon thermal excitation is obtained. In particular the physical properties of the carrier are affected by the additional component. It has been evident that adding a semiconductor material allows a carrier to be obtained that is suitable for the emission of infrared radiation at high irradiation intensity. At the same time, the composite material shows a temperature-dependent thermal conductivity that is also based on the addition of the semiconductor material.

In this context, the composite material includes the following components:

The amorphous matrix component accounts for the largest fraction of the composite material in terms of weight and volume. The matrix component is decisive for the mechanical and chemical properties of the composite material, for example, the temperature resistance, the strength, and the corrosion properties thereof. Since the matrix component is amorphous—it preferably consists of glass—the geometrical shape of the carrier can be adapted to the existing requirements of the specific application of the infrared panel radiator more easily than a carrier made of crystalline materials.

The matrix component can consist of undoped or doped quartz glass and, if applicable, can contain oxidic, nitridic or carbidic components aside from SiO₂ in an amount of maximally 10% by weight. In order to prevent any risk of contamination arising from the carrier material, an embodiment of the infrared panel radiator, in which the amorphous matrix component is quartz glass and preferably has a chemical purity of at least 99.99% SiO₂ and a cristobalite content of no more than 1%, has proven to be particularly expedient.

Moreover, according to exemplary aspects of the invention, an additional component, in the form of a semiconductor material, is embedded in the matrix component. It forms an inherent amorphous or crystalline phase that is dispersed in the amorphous matrix component. It contributes to high emissivity such that a suitable carrier for the emission of infrared radiation at high radiation power is obtained.

The printed conductor applied to the printed conductor occupation surface in the infrared panel radiator according to exemplary embodiments of the invention serves directly for heating of another component, namely of the carrier. The printed conductor acts as a “local” heating element by means of which at least a partial area of the carrier can be locally heated; it is dimensioned appropriately such that it heats a part of the carrier that is made from the composite material, which forms the actual infrared radiation-emitting element of the carrier. Since the printed conductor connected to the carrier is in direct contact with the printed conductor occupation surface of the carrier, a particularly compact infrared panel radiator is obtained.

The printed conductor design and the electrical circuiting of the printed conductor sections are adapted to the physical properties of the thermally-excitable composite material.

The heating power of conventional infrared panel radiators, in which the printed conductor is the actual heating element, follows Ohm's law and depends on the total electrical resistance of the printed conductor; the heating power of these can be increased by selecting the overall resistance value of the printed conductor to be as low as possible. For this reason, the use of a parallel circuiting of the printed conductor sections has proven to be particularly favorable, since it allows a total resistance to be attained that is less than the smallest individual resistance.

In contrast, the infrared panel radiator according to exemplary embodiments of the invention shows a material-related absorption range, in which thermal excitation of the carrier is feasible. Since the power per unit area depends on the absorption range, it is not the lowest possible total resistance that is desired—unlike in conventional infrared panel radiators—but rather it has been evident that an optimized efficient heating power can be attained if the power values per unit area of the printed conductors and, along with them, their total resistance is adapted to the material-related absorption range.

To obtain an optimal irradiation intensity, sufficient thermal excitation of the carrier is required. This is attained if the printed conductor and its sections are circuited appropriately such that sufficient energy for thermal excitation of the carrier is available. The input of more energy contributes only to a limited degree to the increase of the radiation intensity and usually is associated with a lower energy efficiency.

The energy required for excitation of the carrier can be made available easily and inexpensively by circuiting printed conductor sections in series. Moreover, referring to the thermally excitable composite material of the carrier, circuiting the printed conductor sections in series is associated with an additional advantage in that excitation at a particularly favorable current-voltage ratio is made feasible. Circuiting the printed conductor resistors in series makes operating voltages in the range of 100 V to 400 V feasible. Simultaneously, the printed conductor sections can be operated at lower operating currents by means of which the service life of the infrared panel radiator according to exemplary embodiments of the invention can be increased.

And lastly, due to the printed conductor sections being circuited in series according to exemplary embodiments of the invention, the printed conductor design can be flexibly adapted to the respective application. In particular, in contrast to a parallel circuiting of printed conductor sections, in which each printed conductor section forms a partial circuit, no partial circuit junctions are required whose position may be predetermined by the total resistance to be attained, which may hamper the ability to design the printing design freely. The printing design being freely selectable enables a heating surface with a particularly homogeneous irradiation intensity such that a particularly homogeneous thermal treatment of the heating goods is made possible.

For compensation of an inhomogeneous temperature distribution, in particular for compensation of conviction-related peripheral effects, the printed conductor of the infrared panel radiator according to exemplary embodiments of the invention includes multiple sections that differ in the power per unit area that can be attained with them, namely at least one first and one second printed conductor section, whereby the occupation density and/or the conductor cross-section of the first and the second printed conductor sections are matched to each other appropriately such that an essentially homogeneous temperature distribution on the heating surface is obtained upon application of a voltage to the printed conductor.

The respective power per unit area of the first and second printed conductor sections can be adjusted by varying the occupation density or by varying the conductor cross-sections of the respective printed conductor sections or by both.

In this context, the power per unit area is defined to be the electrical connected load of the printed conductor relative to the carrier surface area occupied by the printed conductor. In this context, the carrier surface area shall be understood to be the surface area that is enclosed by an enveloping line about the printed conductor, whereby the enveloping lines of neighbouring printed conductor sections with no distance between them extend in the middle between the neighbouring printed conductors and current feed lines that may be present are not taken into consideration. Accordingly, the carrier surface area reflects the individual surface region that is assigned to a printed conductor section. The power per unit area in a printed conductor section is the higher the higher the occupation density of the printed conductor and the lower the conductor cross-section of the printed conductor.

The printed conductor cross-section is the cross-sectional area through the printed conductor viewed in the direction of current flow. In the case of a rectangular layer-shaped printed conductor, the conductor cross-section is obtained by multiplication of the width of the layer and the thickness of the layer.

The occupation density is a measure of how tightly a carrier section is occupied by a printed conductor. The occupation density is given in units of percent as a ratio of surface areas by relating the surface area occupied by the printed conductor (as a projection onto the printed conductor occupancy area) to the carrier surface area. In this context, the carrier surface area includes both the surface of the printed conductor occupancy area that is occupied by the printed conductor and the “free” surface area of the printed conductor occupancy area that is not occupied by the printed conductor.

Since the printed conductor includes multiple printed conductor sections of this type, the formation of heating zones differing in their power per unit area is made possible. The heating zones can be arranged appropriately such that temperature losses of the heating surface are compensated for, such that a heating surface with a homogeneous irradiation intensity is obtained. Specifically, it is feasible to compensate for peripheral effects, for example, a printed conductor section with a higher power per unit area is assigned to a peripheral zone of the printed conductor occupancy area.

An infrared panel radiator of this type includes a heating surface that is designed for attaining irradiation intensities above 200 kW/m², preferably in the range of 200 kW/m² to 250 kW/m².

In a preferred refinement of the infrared panel radiator according to certain exemplary embodiments of the invention, the entire carrier is made from the composite material, whereby the composite material is an electrical insulator.

The carrier can be designed to be multi-layered and can contain regions made of other materials aside from the composite material. However, it is essential to the operation of the infrared panel radiator that the carrier surface is made of an electrically insulating material, at least in the region of the printed conductor occupation surface. This ensures operation of the infrared panel radiator with little interference, in particular flashovers and short-circuits between neighbouring printed conductor sections are prevented. Since the composite material is an electrical insulator, it is possible to apply the printed conductor directly to the composite material and thus to the carrier.

A carrier made of multiple materials can include, for example, a layered structure, in which two or more layers of material can be arranged on top of each other. Alternatively, it is possible just as well that the carrier includes a core made of a first material, preferably of the composite material, that is coated by a coating made of a second material. All or part of the core can be coated by the second material. Preferably, the core is fully coated by the second material.

In a preferred refinement of the infrared panel radiator according to exemplary embodiments of the invention, the composite material is coated with a layer made of an electrically insulating material, at least in the region of the printed conductor occupation surface.

The composite material of which the carrier is made shows good emissivity in the infrared range. Aside from the emissivity of the composite material, other physical properties of the composite material, in particular its electrical conductivity, are important for its suitability as a carrier of an infrared panel radiator. The physical properties of the composite material are determined mainly by the components of which the composite material is composed. Accordingly, depending on the chemical composition, the composite material may either be an electrical insulator or have a certain electrical conductivity. For the reasons specified above, an electrically conductive composite material cannot be directly provided with a printed conductor since this may give rise to short-circuiting during the operation of the infrared panel radiator. To be able to manufacture a carrier from an electrically conductive composite material regardless, it has proven to be expedient to initially coat the composite material with a layer made of an electrically insulating material. All or part of the composite material can be coated by an electrically insulating material. In any case, at least the region of the carrier that has the printed conductor assigned to it—i.e., the printed conductor occupation surface—should be coated by a layer made of an electrically insulating material, for example, by a layer made of glass, in particular made of quartz glass.

A further preferred refinement of the infrared panel radiator according to exemplary embodiments of the invention provides the weight fraction of the additional component to be in the range of 1% to 5%, preferably in the range of 1.5% to 3.5%.

The heat absorption of the composite material depends on the fraction of the additional component. The weight fraction of the additional component should therefore preferably be at least 1%. On the other hand, the volume fraction of the additional component being high can have an adverse effect on the chemical and mechanical properties of the matrix. Taking this into consideration, the weight fraction of the additional component is preferably in the range of 1% to 5%, more preferably in the range of 1.5% to 3.5%.

It has proven to be expedient to provide the printed conductor in the form of a burnt-in thick film layer or to apply it appropriately, as a form part, to the surface of the carrier such that the printed conductor and the carrier are permanently connected to each other.

A printed conductor can be produced through a variety of manufacturing methods, for example, through the use of printing techniques, but also by punching, laser cutting or casting.

It has proven to be particularly expedient to provide the printed conductor as a burnt-in thick film layer. Such thick film layers are generated, for example, from resistor paste by means of screen printing or from metal-containing ink by means of inkjet printing, and are subsequently burned-in at high temperature. Alternatively, a form part can just as well be made from a sheet of metal using a thermal separating procedure, for example, by laser cutting or by punching. The use of thermal separating or punching procedures allows printed conductors to be manufactured in large quantities and thus contributes to keeping the material and production costs low.

The use of thermal separating and punching procedures allows even materials that are difficult or laborious to process by printing techniques to be processed to form a printed conductor. Since the printed conductor is manufactured from a resistor material that is electrically conductive and generates heat when current flows through it, the printed conductor acts as heating element. However, an infrared panel radiator that emits panel-like and homogeneously at high radiation power is obtained only after the printed conductor is connected to the carrier. For this purpose, e.g., the printed conductor is applied to the surface of the carrier as a form part and is permanently connected to the carrier. In this context, the printed conductor can be joined to the carrier both by mechanical and thermal means and by means of a non-conductive layer. In the simplest case, the printed conductor is joined to the carrier in loose contact with each other.

Moreover, the use of thermal separating or punching procedures allows fabrication errors that might occur during the production of the printed conductor to be detected early. In particular, in contrast to a printed conductor that is manufactured through the use of printing techniques, it is feasible to check the printed conductor form parts for their functional capability before the process step of joining them to the carrier. For example, it is easy to apply a voltage to the printed conductor, if same is a separate component. By this means, a faulty printed conductor can be rejected and this can be done before connecting the faulty printed conductor to the carrier such that less scrap is produced and the production costs can therefore be lowered by this means.

It has proven to be expedient to manufacture the printed conductor from platinum, high temperature-resistant steel, tantalum, a ferritic FeCrAl alloy, an austenitic CrFeNi alloy, silicon carbide, molybdenum disilicide or a molybdenum basic alloy.

The aforementioned materials, in particular silicon carbide (SiC), molybdenum disilicide (MoSi₂), tantalum (Ta), high temperature-resistant steel or a ferritic FeCrAl alloy such as Kanthal® (Kanthal is a registered trademark of SANDVIK INTELLECTUAL PROPERTY AB, 811 81, Sandviken, SE) are inexpensive as compared to precious metal, for example, gold, platinum or silver; they are easy to form into a printed conductor form body that can be used as semi-finished goods in the production of the infrared panel radiator. In particular, they are available as metal sheets from which the printed conductor can be fabricated easily and inexpensively. Moreover, the aforementioned materials are advantageous in that they are oxidation-resistant on air such that an additional layer covering the printed conductor (cover layer) for protection of the printed conductor is not mandatory.

The heating power of each printed conductor section depends on the specific resistance of the resistor material, the length of the printed conductor section, as well as the conductor cross-section. The heating power of the printed conductor section can be adjusted easily and quickly by adjusting the length and the conductor cross-section.

In this context: The larger the conductor cross-section of the printed conductor section, the lower is its resistance and the lower is its power per unit area at constant supply voltage. The overall resistance and the current flow at a constant supply voltage result from the sum of the resistors circuited in series. A higher power per unit area can be generated by means of a higher occupation density using conductors of the same cross-section or by increasing the current density or by means of a thinner conductor cross-section.

Therefore, it has been particularly expedient for the conductor cross-section of the printed conductor of the first printed conductor section to be in the range of 0.01 mm² to 0.03 mm² and the conductor cross-section of the printed conductor of the second printed conductor section to be between 0.025 mm² and 0.5 mm².

It has been evident that good results with respect to the compensation of inhomogeneities of the irradiation intensity, which are commonly observed with infrared panel radiators, can be attained if the conductor cross-sectional areas of the first and second printed conductor section differ from each other by at least 25%. Preferably, the difference of the conductor cross-sections between the first and the second printed conductor section are in the range of 30% to 70%. Conductor cross-sections of less than 0.01 mm² may be difficult to apply and their mechanical adhesion is poor. Conductor cross-sections in excess of 0.5 mm result in a comparably low resistance and therefore necessitate relatively high operating currents for heating.

Conductor cross-sections in the range of 0.01 to 0.5 mm² are characterised by a particularly favorable voltage/current ratio; they make feasible, in particular, operation with voltages in the range of 100 V to 400 V at currents of 1 A to 4.5 A.

The length of the printed conductor can be varied by suitable selection of the shape of the printed conductor. With regard to a temperature distribution being as homogeneous as possible, it has proven to be advantageous to provide the printed conductor as a line pattern covering a surface of the carrier such that an intervening space of at least 1 mm, preferably at least 2 mm, remains between neighbouring sections of printed conductor.

Advantageously, the printed conductor is provided as a line pattern with an occupation density in the range of 25% to 85%.

At a low occupation density of less than 25%, the printed conductor may stand out on the side of the heating surface as an inhomogeneity in the temperature profile. Increasing the occupation density to more than 85% attains no significant increase in the power per unit area. The first and the second printed conductor sections can have the same or different occupation densities. The occupation density can be used for adjustment of the power per unit area. In this context, the adjustment of the power per unit area can take place either by a suitable selection of the occupation density and by a suitable selection of the conductor cross-sections. A printed conductor section with higher power per unit area is obtained, if its conductor cross-section is low or if the printed conductor section has a high occupation density. The power per unit area of the first and second printed conductor sections can be adjusted very accurately if the printed conductor sections differ by both their conductor cross-section and their occupation density.

Preferably, the occupation density of the first printed conductor section is maximally 75% and the occupation density of the second printed conductor section is in the range of maximally 85%. The aforementioned occupation densities of the first and second printed conductor sections can be produced easily and inexpensively, for example, by printing.

A preferred refinement of the infrared panel radiator according to exemplary embodiments of the invention provides the printed conductor to include multiple first printed conductor sections and multiple second printed conductor sections, whereby first and second printed conductor sections alternate in sequence.

Providing multiple sequential printed conductor sections allows for particularly flexible adjustment of the irradiation intensity, and therefore of the temperature distribution, on the heating surface such that the formation of so-called “cold spots” or “hot spots” can be prevented. Since the multiple printed conductor sections are circuited in series, virtually any printed conductor design can be implemented.

It has been particularly expedient to arrange, between the first printed conductor section and the second printed conductor section, a third printed conductor section for generation of a gradient of the power per unit area.

A printed conductor section corresponds to a part of the heating surface that is heated at a constant power per unit area. The first and second printed conductor sections can be immediately adjacent or can be at a distance from each other. A gradual transition between the first and the second print conductor sections contributes to attaining an irradiation power that is as homogeneous as possible and a homogeneous temperature distribution on the heating surface. For this purpose, a third printed conductor section can be arranged between the first and the second printed conductor sections and can be designed appropriately such that it generates a gradient of the power per unit area. This provides for a continuous transition from the first power per unit area of the first printed conductor section to the second power per unit area of the second printed conductor section. In the simplest case, the third printed conductor section is designed appropriately such that the power per unit area in the third printed conductor section transitions from the first power per unit area to the second power per unit area.

A preferred refinement of the infrared panel radiator according to exemplary embodiments of the invention provides the printed conductor occupation surface to include a peripheral region and a middle region, whereby the first printed conductor section has a higher power per unit area than the second printed conductor section and is assigned to the peripheral region, and the second printed conductor section is assigned to the middle region.

It has been evident that the peripheral region of an infrared panel radiator often has a lower temperature than the middle region. One reason for this phenomenon is that the peripheral region, due to its spatial arrangement, is more accessible to heat dissipation than the middle region. Therefore, it has proven to be expedient to assign, in particular to the peripheral region, a printed conductor section with a higher power per unit area that can compensate for the heat dissipation. This can be attained, for example, by the outer zone having a higher occupation density or a lower conductor cross-section.

The additional component is decisive for the optical and thermal properties of the carrier; to be more specific, it effects an absorption in the infrared spectral range, which is the wavelength range between 780 nm and 1 mm. The additional component shows an absorption that is higher than that of the matrix component for at least part of the radiation in this spectral range.

The phase areas of the additional component in the matrix act as optical defects and cause, for example, the composite material to appear black or grey-blackish by eye at room temperature, depending on the thickness of the layer. Moreover, the defects also have a heat-absorbing effect.

The type and amount of the additional component present in the composite material are preferably appropriate such as to effect, in the composite material at a temperature of 600° C., an emissivity 6 of at least 0.6 for wavelengths between 2 μm and 8 μm. In a particularly preferred embodiment of the infrared panel radiator according to exemplary embodiments of the invention, the type and amount of the additional component are such as to effect, in the substrate material at a temperature of 1,000° C., an emissivity ε of at least 0.75 for wavelengths between 2 μm and 8 μm.

Accordingly, the area material has high absorption and emission power for heat radiation between 2 μm and 8 μm, i.e., in the wavelength range of infrared radiation. This reduces the reflection at the carrier surfaces such that, on the assumption of the transmission being negligibly small, the resulting degree of reflection for wavelengths between 2 μm and 8 μm and at temperatures above 1,000° C. is maximally 0.25 and at temperatures above 600° C. is maximally 0.4. Non-reproducible heating by reflected thermal radiation is thus prevented which contributes to a uniform or desired non-uniform temperature distribution.

Particularly high emissivity can be attained if the additional component is present as an additional component phase and has a non-spherical morphology with maximal mean dimensions of less than 20 μm, but preferably of more than 3 μm.

In this context, the non-spherical morphology of the additional component phase also contributes to the composite material having high mechanical strength and a low tendency to form cracks. The term “maximal dimension” shall refer to the longest extension of an isolated area of the additional component phase as visible in a microphotograph. The mean mentioned above is the median of all longest extensions in a microphotograph.

According to Kirchhoff's law of thermal radiation, the absorptivity α_{λ}, and the emissivity ε_{λ} of a real body in thermal equilibrium are equal.

α_{λ}=ε_{λ} (1)

Accordingly, the additional component leads to the emission of infrared radiation by the carrier material. The emissivity ε_{λ} can be calculated as follows if the spectral hemispherical reflectance R_{gh} and transmittance T_{gh} are known:

ε_{λ}=1−R_{gh}−T_{gh} (2)

In this context, the “emissivity” shall be understood to be the “spectral normal degree of emission”. Same is determined by means of a measuring principle that is known by the name of “Black-Body Boundary Conditions” (BBC) and is published in “DETERMINING THE TRANSMITTANCE AND EMITTANCE OF TRANSPARENT AND SEMITRANSPARENT MATERIALS AT ELEVATED TEMPERATURES”; J. Manara, M. Keller, D. Kraus, M. Arduini-Schuster; 5th European Thermal-Sciences Conference, The Netherlands (2008).

The amorphous matrix component has a higher heat radiation absorption in the composite material, i.e., in combination with the additional component, as compared to when the additional component is absent. This results in an improved thermal conductivity from the printed conductor into the carrier, more rapid distribution of the heat, and a higher rate of emission towards the carrier. By this means, it is feasible to provide higher radiation power per unit area and to generate a homogeneous emission and a uniform temperature field even for thin carrier walls and/or at a comparably low printed conductor occupation density. A carrier with a low wall thickness has a low thermal mass and allows for rapid temperature changes. Cooling is not required for this purpose.

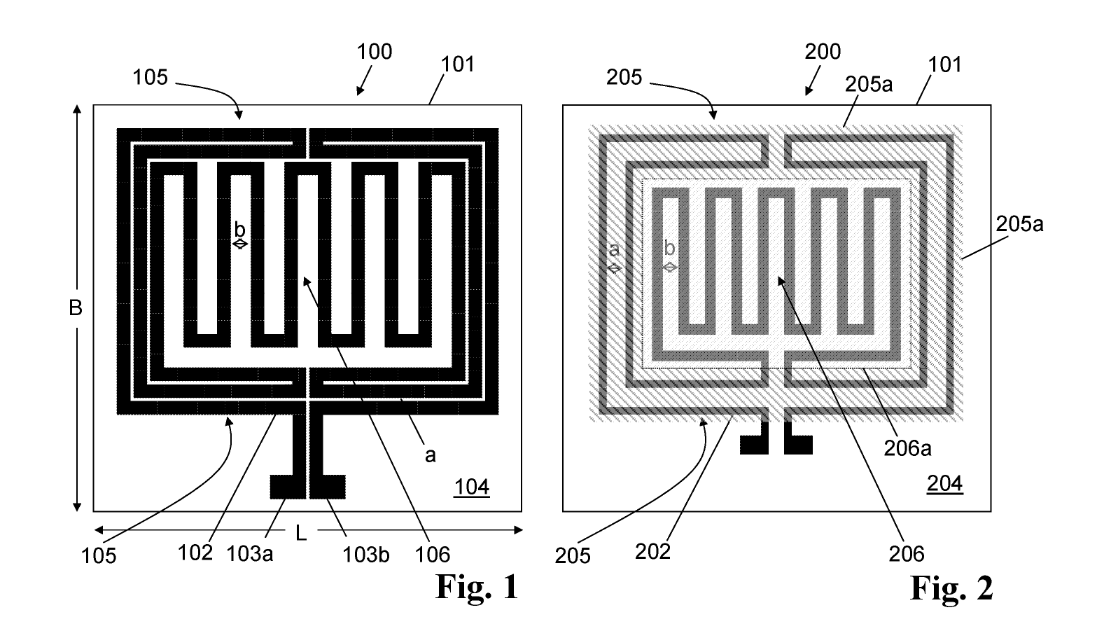

FIG. 1 shows a top view of a first embodiment of an infrared panel radiator according to an exemplary embodiment of the invention, which, in toto, has reference number 100 assigned to it. The infrared panel radiator 100 is suitable for use in a device for the production of flexible printed electronics (not shown). It includes a plate-shaped substrate (this is the carrier in the scope of this invention) 101, a printed conductor 102 applied to the substrate 101, as well as two printed conductors 103a, 103b for electrical contacting of the printed conductor 102.

The plate-shaped substrate 101 is made of quartz glass with a chemical purity of 99.99% and a cristobalite content of 0.25% to which has been added elemental silicon in an amount of 5% of the total mass. The elemental silicon phase is distributed homogeneously in the quartz glass in the form of non-spherical regions. The maximum mean dimensions of the Si phase areas (median) are in the range of approximately 1 μm to 10 μm. The plate-shaped substrate 101 has a density of 2.19 g/cm³, and it has a length L of 100 mm, a width B of 100 mm, and a thickness of 2 mm. The plate-shaped substrate 101 appears black by eye.

The embedded Si phase contributes not only to the overall opacity of the substrate 101, but also has an impact on the optical and thermal properties of the substrate 101. The substrate shows high absorption of heat radiation and high emissivity at high temperatures.

At room temperature, the emissivity of the composite material is measured using an integrating sphere. This allows for measurement of the spectral hemispherical reflectance R_{gh} and of the spectral hemispherical transmittance T_{gh} from which the normal emissivity can be calculated. The emissivity at elevated temperature is measured in the wavelength range from 2 to 18 μm by means of an FTIR spectrometer (Bruker IFS 66v Fourier Transformation Infrared (FTIR)) to which a BBC sample chamber is coupled by means of an additional optical system, applying the above-mentioned BBC measuring principle. In this context, the sample chamber is provided with thermostatted black body environments in the semi-spheres in front of and behind the sample holder, and with a beam exit opening with a detector. The sample is heated to a predetermined temperature in a separate furnace and, for the measurement, is transferred into the beam path of the sample chamber with the black body environments set to the predetermined temperature. The intensity detected by the detector is composed of emission, reflection, and transmission portions, namely intensity emitted by the sample itself, intensity that is incident on the sample from the front hemisphere and is reflected by the sample, and intensity that is incident on the sample from the back hemisphere and is transmitted by the sample. Three measurements need to be performed to determine the individual parameters, i.e., the degrees of emission, reflection, and transmission.

The degree of emission measured on the substrate 101 in the wavelength range of 2 μm to approximately 4 μm is a function of the temperature. The higher the temperature, the higher is the emission. At 600° C., the normal degree of emission in the wavelength range of 2 μm to 4 μm is above 0.6. At 1000° C., the normal degree of emission in the entire wavelength range of 2 μm to 8 μm is above 0.75.

The printed conductor 102 is generated from a platinum resistor paste by applying the paste to the printed conductor occupation surface 104 of the plate-shaped substrate 101 and subsequently burning it in. The printed conductor 102 has a meandering profile and includes two printed conductor sections 105, 106, whereby the first printed conductor section 105 is assigned to the peripheral region of the substrate 101 and the second printed conductor section 106 is assigned to the middle region of the substrate 101. To be able to counteract a convection-related inhomogeneous temperature distribution of the substrate 101, the printed conductor section 105 assigned to the peripheral region is applied to the substrate 101 at a higher occupation density than the printed conductor section 106 assigned to the middle region. The occupation density of printed conductor section 105 is 80% and the occupation density of printed conductor section 106 is 40%, the distance b of neighbouring printed conductors in the middle region is 4.2 mm, the distance a of neighbouring printed conductors in the peripheral region is 0.7 mm.

The printed conductor sections 105, 106 are characterised by a cross-sectional area of 0.028 mm², a width of 2.8 mm, and a thickness of 10 μm.

In as far as the same reference numbers as in FIG. 1 are used in the embodiments shown in other figures, these denote components and parts that are identical in design or equivalent as illustrated in more detail above by means of the description of FIG. 1.

FIG. 2 shows a second embodiment of an infrared panel radiator according to an exemplary embodiment of the invention, which, in toto, has reference number 200 assigned to it. The infrared panel radiator 200 includes a plate-shaped substrate 101, a printed conductor 202 that is applied to the substrate 101, as well as two printed conductors 103a, 103b.

The infrared panel radiator 200 differs from the infrared panel radiator 100 known from FIG. 1 essentially by the printed conductor design. With regard to the substrate 101, reference shall be made to the description of FIG. 1.

The printed conductor 202 is generated from a platinum resistor paste by applying the paste to the top side 204 of the plate-shaped substrate 101 and subsequently burning it in. The printed conductor 202 has a meandering profile and includes two printed conductor sections 205, 206, whereby the first printed conductor section 205 is assigned to the peripheral region of the substrate 101 and the second printed conductor section 206 is assigned to the middle region of the substrate 101. To be able to counteract a convection-related inhomogeneous temperature distribution on the substrate 101, the printed conductor section 205 assigned to the peripheral region has a higher resistance than the printed conductor section 206 assigned to the middle region. The printed conductor section 205 has a cross-sectional area of 0.02 mm² and a width of 0.02 mm and a thickness of 10 μm. The printed conductor section 206 has a cross-sectional area of 0.028 mm² and a width of 2.8 mm and a thickness of 10 μm.

The distance b of neighbouring printed conductors in the middle region is 4.18 mm, whereas the distance of a neighbouring printed conductors in the peripheral region is 4.98 mm. However, the printed conductor width (and thus the conductor cross-section) is larger in the middle region 206 than in the peripheral region 205 such that the sections 205, 206 do not have a uniform printed conductor occupation density. The occupation density is 40% in the middle region 206 and 28.8% in the peripheral region, relative to the carrier surface area occupied by the perspective printed conductor, which is represented by surface regions 205a (for the carrier surface area of the peripheral region 205) and 206a (for the carrier surface area of the middle region 206) shown with a grey background.

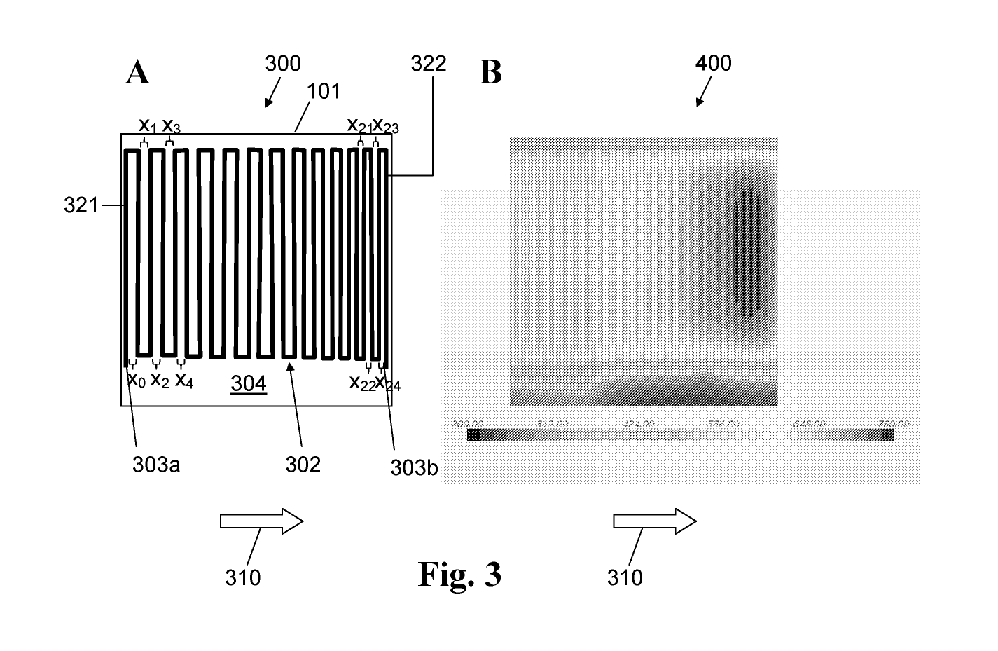

FIG. 3 (part “A”) shows a third embodiment of an infrared panel radiator according to an exemplary embodiment of the invention, which, in toto, has reference number 300 assigned to it. The infrared panel radiator 300 includes a substrate 101 of the type described in more detail through FIG. 1. A printed conductor 302 that is provided on its ends with printed conductors 303a, 303b is applied to the substrate 101. The printed conductor 302 is designed for generation of a temperature gradient.

For this purpose, the printed conductors 302 applied to the surface 304 of the substrate 101 are designed appropriately such that the distances x₀ to x₂₂ of neighbouring printed conductors decrease continuously in the direction of the arrow 310 such that the occupation density increases as seen in the direction of the arrow 310. The occupation density in the first printed conductor end section 321 is 40% and it increases continuously up to 91% in the second printed conductor end section 322.

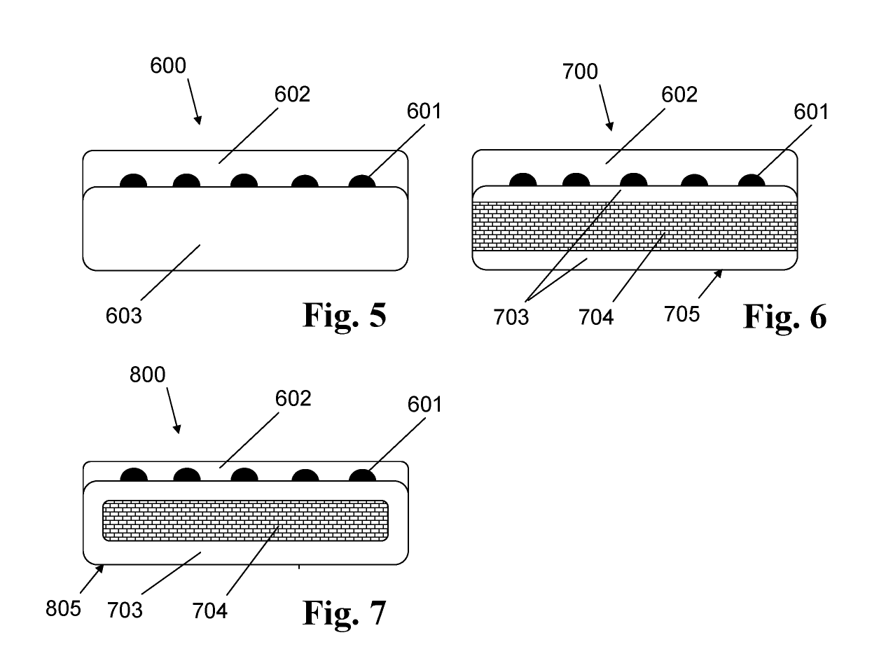

The printed conductors 302 are generated by screen printing, as is illustrated in more detail below based on the exemplary embodiment of FIG. 5. The printed conductor 302, seen in the direction of the arrow 310, has a meandering profile. The printed conductor 302 has a cross-sectional area of 0.02 mm² and a width of 0.1 mm and a thickness of 20 μm.

The infrared panel radiator 300 can be used in a device (not shown) designed for the production of flexible printed electronics in the reel-to-reel procedure (R2R procedure). In this device, the infrared panel radiator 300 is arranged appropriately such that the transport direction (from reel to reel) corresponds to the direction of the arrow 310. As a result, a low power is provided at the beginning of the irradiation, as is required, for example, for drying the printed electronics. Since the occupation density of the infrared panel radiator 300 increases in the direction of transport, the heating goods is irradiated with steadily increasing irradiation power during its transport until it is exposed to high power at the end of the irradiation process, as is required, for example, for the sintering of the printed electronics. The irradiation power at the start of the irradiation process is 50 kW/m² and increases continuously to reach 150 kW/m² at the end.

This gradient is also reflected in the temperature distribution on the heating surface of the infrared panel radiator 300. FIG. 3 (part “B”) shows a diagram 400 of the temperature distribution on the heating surface of the infrared panel radiator 300. The temperature of the heating surface increases continuously in the direction of the arrow 310 as a function of the occupation density, and does so starting from a mean temperature of approximately 550° C. in the left field of the infrared panel radiator 300 up to a temperature of 760° C. in the right field of the infrared panel radiator 300.

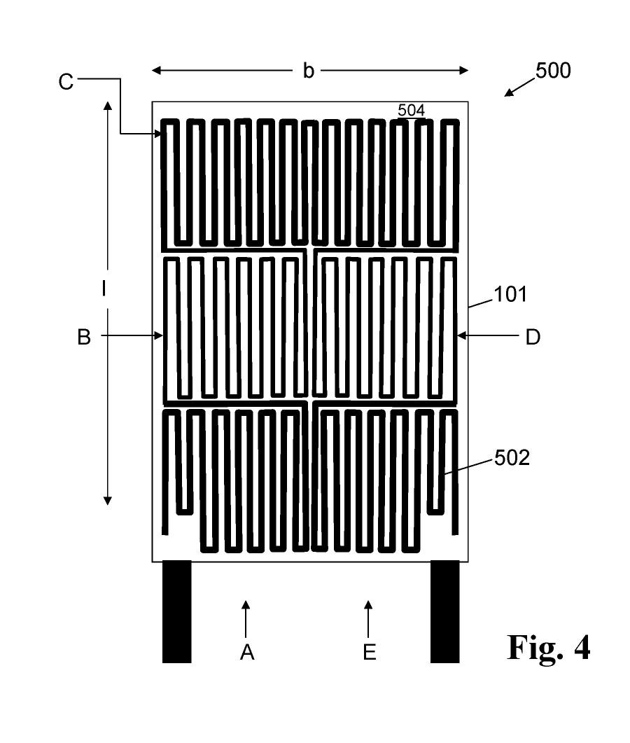

FIG. 4 shows a fourth embodiment of an infrared panel radiator according to an exemplary embodiment of the invention, which, in toto, has reference number 500 assigned to it. The infrared panel radiator 500 includes a plate-shaped substrate 101 onto which a printed conductor 502 is applied by means of screen printing, as is illustrated in the exemplary embodiment of FIG. 5 described below.

With regard to the substrate 101, reference shall be made to the description of FIG. 1. Deviating from the substrate 100 from FIG. 1, it has a length l of 200 mm, a width b of 100 mm, and a thickness of 2 mm.

The printed conductor 502 includes five printed conductor sections circuited in series that are identified by reference letters A through E. Printed conductor sections B, D are identical in design; they have a cross-sectional area of 0.01 mm² and a width of 0.05 mm and a thickness of 20 μm. Printed conductor sections A, E are also identical in design and have a cross-sectional area of 0.02 mm² and a width of 0.1 mm and a thickness of 20 μm. Printed conductor section C has the same printed conductor width and the same conductor cross-section as sections A, E, and differs from sections A, E only by its length. Section B has the same printed conductor occupation density as section D. But the printed conductor width in these sections is only half of that in the other sections A, E, and C. Therefore, the printed conductor occupation density in sections B and D is only 50% of what it is in the other sections.

FIG. 5 shows an embodiment of an infrared panel radiator 600 according to an exemplary embodiment of the invention with a substrate 603, a printed conductor 601 with five printed conductor sections applied to the substrate 603, and a cover layer 602 covering the printed conductor 601.

The substrate 603 is manufactured from the same material as the plate-shaped substrate 101 in FIG. 1. Reference shall be made to the pertinent explanations provided in the context of FIG. 1. The composite material from which the substrate 603 is made is an electrical insulator. It consists of a matrix component in the form of quartz glass. A phase of elemental silicon is homogeneously distributed in the matrix in the form of non-spherical areas, which account for the weight fraction of 5%. The maximum mean dimensions of the silicon phase areas (median) are in the range of approximately 1 μm to 10 μm. The composite material is gas-tight, it has a density of 2.19 g/cm³ and it is stable on air up to a temperature of approximately 1150° C. The composite material shows high absorption of heat radiation and high emissivity at high temperatures. This is a function of the temperature. At 600° C., the normal degree of emission in the wavelength range of 2 μm to 4 μm is above 0.6. At 1000° C., the normal degree of emission in the same wavelength range is above 0.75.

The printed conductor 601 is produced from a platinum paste that was applied to the substrate 603 by means of screen printing and was subsequently burned-in. A thin cover layer 602 made of quartz glass is applied to the printed conductors 601. The cover layer made of SiO₂ was applied by screen printing using the thick film procedure and has a mean layer thickness of 20-50 μm. The layer is free of cracks and pores in order to protect the platinum from corrosive attacks.

In as far as the same reference numbers as in FIG. 5 are used in the embodiments shown in FIGS. 6 and 7, these denote components and parts that are identical in design or equivalent as illustrated in more detail above by means of the description of FIG. 5.

FIG. 6 shows another embodiment of an infrared panel radiator 700 according to an exemplary embodiment of the invention. The infrared panel radiator 700 differs from the infrared panel radiator 600 from FIG. 5 by its substrate composition. The substrate 705 is made of two materials that are connected to each other in the form of layers. The mean layer 704 consists of a conductive material with high emissivity, namely of SiC. Due to its electrical conductivity, the printed conductor 601 cannot be placed directly on the layer 704. For this reason, the layer 704 is covered on its top and bottom side by a layer 703 each that is made of quartz glass. The layers 703 differ in their layer thickness.

FIG. 7 shows a seventh embodiment of an infrared panel radiator according to an exemplary embodiment of the invention, which, in toto, has reference number 800 assigned to it. The infrared panel radiator 800 includes a substrate 805 that consists of the same materials as the substrate 705 from FIG. 6. The material 704 forms a substrate core that is surrounded by a layer of the material 703, the carrier, whereby the printed conductor includes a first printed conductor section for generation of a first power per unit area and a second printed conductor section for generation of a second power per unit area that differs from the first power per unit area. To devise, on this basis, an infrared panel radiator with high irradiation power that is designed to emit radiation at the highest possible uniform irradiation intensity, the invention proposes that the carrier contains a composite material that includes an amorphous matrix component and an additional component in the form of a semiconductor material, and that the first printed conductor section and the second printed conductor section are circuited in series and differ from each other by their occupation density and/or by their conductor cross-section.

Although the invention is illustrated and described herein with reference to specific embodiments, the invention is not intended to be limited to the details shown. Rather, various modifications may be made in the details within the scope and range of equivalents of the claims and without departing from the invention.

1. An infrared panel radiator comprising,
a carrier with a heating surface and with a printed conductor that is made of an electrically conductive resistor material that generates heat when current flows through it, the printed conductor being applied to a printed conductor occupation surface of the carrier, whereby the printed conductor includes a first printed conductor section for generation of a first power per unit area and a second printed conductor section for generation of a second power per unit area that differs from the first power per unit area, wherein the carrier contains a composite material that includes an amorphous matrix component and an additional component in the form of a semiconductor material, and in that the first printed conductor section and the second printed conductor section are circuited in series and differ from each other by at least one of (i) their occupation density and (ii) their conductor cross-section.

2. The infrared panel radiator according to claim 1, wherein the entire carrier is made from the composite material, whereby the composite material is an electrical insulator.

3. The infrared panel radiator according to claim 1, wherein the composite material is coated with a layer made of an electrically insulating material, at least in the region of the printed conductor occupation surface.

4. The infrared panel radiator according to claim 1, wherein a weight fraction of the additional component is in a range of 1% to 5%.

5. The infrared panel radiator according to claim 1, wherein the printed conductor is provided (i) as a burnt-in thick film layer or (ii) is applied appropriately, as a form part, to the printed conductor occupation surface of the carrier such that the printed conductor and the carrier are permanently connected to each other.

6. The infrared panel radiator according to claim 1, wherein the printed conductor is provided as a line pattern with an occupation density of the range of 25% to 85%.

7. The infrared panel radiator according to claim 1, wherein the printed conductor in the first printed conductor section has a conductor cross-section in the range of 0.01 to 0.03 mm² and the printed conductor in the second printed conductor section has a conductor cross-section in the range of 0.025 to 0.5 mm².

8. The infrared panel radiator according to claim 1, wherein the printed conductor includes a plurality of first printed conductor sections and a plurality of second printed conductor sections, whereby the first conductor sections and the second printed conductor sections alternate in sequence.

9. The infrared panel radiator according to claim 1, wherein a third printed conductor section for generation of a gradient of the power per unit area is arranged between the first printed conductor section and the second printed conductor section.

10. The infrared panel radiator according to claim 1, wherein the printed conductor occupation surface includes a peripheral region and a middle region, whereby the first printed conductor section has a higher power per unit area than the second printed conductor section and is assigned to the peripheral region, and the second printed conductor section is assigned to the middle region.

11. The infrared panel radiator according to claim 1 the heating surface has an irradiation power in the range of 200 kW/m² to 250 kW/m².

12. The infrared panel radiator according to claim 2 wherein a weight fraction of the additional component is in a range of 1% to 5%.

13. The infrared panel radiator according to claim 3 wherein a weight fraction of the additional component is in a range of 1% to 5%.

14. The infrared panel radiator according to claim 2 wherein a weight fraction of the additional component is in a range of 1.5% to 3.5%.

15. The infrared panel radiator according to claim 3 wherein a weight fraction of the additional component is in a range of 1.5% to 3.5%.

16. The infrared panel radiator according to claim 2 wherein the printed conductor is provided (i) as a burnt-in thick film layer or (ii) is applied appropriately, as a form part, to the printed conductor occupation surface of the carrier such that the printed conductor and the carrier are permanently connected to each other.

17. The infrared panel radiator according to claim 3 wherein the printed conductor is provided (i) as a burnt-in thick film layer or (ii) is applied appropriately, as a form part, to the printed conductor occupation surface of the carrier such that the printed conductor and the carrier are permanently connected to each other.

18. The infrared panel radiator according to claim 4 wherein the printed conductor is provided (i) as a burnt-in thick film layer or (ii) is applied appropriately, as a form part, to the printed conductor occupation surface of the carrier such that the printed conductor and the carrier are permanently connected to each other.

19. The infrared panel radiator according to claim 2 wherein the printed conductor is provided as a line pattern with an occupation density of the range of 25% to 85%.

20. The infrared panel radiator according to claim 3 wherein the printed conductor is provided as a line pattern with an occupation density of the range of 25% to 85%.
